(19) United States
(12) Patent Application Publication
(10) Pub. No.: US 2008/0047489 A1
(43) Pub. Date: Feb. 28, 2008

(54) Chemical vapor deposition reactor that pre-heats applied gas and substrate before reaction

(75) Inventors: Chih-Hsien Chung, Yingge Township (TW); Hsiao-Kuo Chang, Taoyuan City (TW); Kuan-Hung Lin, Banciao City (TW)

Correspondence Address: BACON & THOMAS, PLLC, 625 SLATERS LANE, FOURTH FLOOR, ALEXANDRIA, VA, 22314, US

(73) Assignee: Kinik Company, Taipei (TW)

(21) Appl. No.: 11/595,903

(22) Filed: Nov. 13, 2006

(30) Foreign Application Priority Data
Aug. 23, 2006 (TW) 095130980

(51) Int. Cl. C23C 16/00

(52) U.S. Cl. 118/715; 118/723 R; 118/724

(57) ABSTRACT

A CVD (chemical vapor deposition) reactor is disclosed to include a reaction chamber, a gas heater, a substrate holder, a substrate heater, hot filaments, an electric field generator, and a magnetic field generator. By means of preheating applied gas with the gas heater and heating the substrate with the substrate holder and the hot filaments, the gas and substrate heating speed is accelerated, thereby saving much deposition time and greatly improving deposition efficiency. Matching with the electric field generator and the magnetic field generator, the ionization of applied gas in the reaction chamber is enhanced and, the uniformity of the thickness of deposition of metal substance on the surface of the substrate(s) is increased.

### BACKGROUND OF THE INVENTION

1. Field of the Invention

The present invention relates to an equipment for chemical vapor deposition and more particularly, to a CVD (chemical vapor deposition) reactor that has applied gas pre-heating, substrate heating, and electric field and magnetic field control means.

2. Description of Related Art

Hot filament CVD (HFCVD) is a kind of chemical vapor deposition. For the advantages of high covering power, high uniformity, high purity, and big area deposition, hot filament CVD is intensively used in making diamond thin films and polysilicon materials.

Basically, hot filament CVD (HFCVD) uses surface high temperature of hot filaments in the reaction chamber of the reactor to cause pyrolysis (thermal cracking) of the gas that passes through the hot filaments so that atoms are deposited to form a thin film on the substrate.

In actual manufacturing application, the reaction temperature of the substrate in the reaction chamber of the reactor is controlled within a predetermined manufacturing condition and the distribution of atoms after pyrolysis of applied gas is also properly defined so that the quality parameters of purity, thickness and uniformity of the deposited thin film are controlled.

However, simply using hot filaments to cause pyrolysis (thermal cracking) of applied gas takes much time, and the temperature of hot filaments must be increased to a certain high level. Therefore, the whole manufacturing process has low performance, wasting much time.

In order to eliminate the aforesaid problem, applied gas may be pre-heated to a certain temperature and then supplied to the reaction chamber for hitting by hot filaments to cause pyrolysis. However, pre-heating applied gas cannot significantly increase the temperature. This method is still not satisfactory in function because it cannot completely eliminate the drawbacks of time-consuming in substrate manufacturing process and uneven thickness of substrate coating.

Therefore, it is desirable to provide a chemical vapor deposition reactor that eliminates the aforesaid problems.

### SUMMARY OF THE INVENTION

The present invention has been accomplished under the circumstances in view. According to the present invention, the chemical vapor deposition reactor comprises a reaction chamber, a gas heater, a substrate holder, a substrate heater, hot filaments, an electric field generator, and a magnetic field generator.

Further, the reaction chamber comprises an enclosed space, a gas intake pipe, and an exhaust port. The gas intake pipe has an outlet suspending in the enclosed space inside the reaction chamber. The gas heater is disposed around the gas intake pipe. The substrate holder is provided in the enclosed space inside the reaction chamber. The substrate heater is mounted in the enclosed space inside the reaction chamber around the substrate holder. The hot filaments are arranged in the enclosed space inside the reaction chamber adjacent to the substrate holder. The magnetic field generator is provided at two opposite sides relative to the substrate holder.

The gas heater is adapted to heat applied gas. The substrate heater and the hot filaments are adapted to heat the substrate(s) carried on the substrate holder. By means of the arrangement of the multiple heaters, the gas and substrate heating speed is accelerated, thereby saving much deposition time and greatly improving deposition efficiency. Matching with the electric field generator and the magnetic field generator, the ionization of applied gas in the reaction chamber is enhanced and, the uniformity of the thickness of deposition of metal substance on the surface of the substrate(s) is increased.

Further, the gas intake pipe can be a snake-shape pipe that extends the gas delivery path in the reaction chamber. Other shapes of pipes may be selectively used as a substitute.

Further, the gas heater can be mounted in the enclosed space inside the reaction chamber and around the periphery of the gas intake pipe, or mounted outside the reaction chamber, i.e., the gas intake pipe and the gas heater can be mounted inside the reaction chamber for enabling applied gas to be pre-heated inside the reaction chamber, alternatively, the gas heater can be provided outside the reaction chamber to pre-heat applied gas outside the reaction chamber.

Further, a gas shower may be mounted in the outlet of the gas intake pipe to let applied gas to evenly applied to the substrate(s), increasing the uniformity of the thickness of deposition of metal substance on the surface of the substrate.

Further, a distribution pipe may be connected to the outlet of the gas intake pipe in the enclosed space inside the reaction chamber so that applied gas is evenly distributed to multiple substrates that are carried on the substrate holder, increasing the uniformity of the thickness of deposition of metal substance on the surface of each substrate.

Further, the outlet of the gas intake pipe is suspending in the enclosed space, and the inlet of the gas intake pipe is disposed at the top side of the enclosed space of the reaction chamber, i.e., applied gas is supplied to the enclosed space from the top side of the reaction chamber. Further, the exhaust port is disposed at the bottom side of the enclosed space of the reaction chamber, i.e., exhaust gas is carried out of the enclosed space through the bottom side of the reaction chamber, thereby increasing the uniformity of the distribution of applied gas in the enclosed space of the reaction chamber.

The vapor deposition reactor further comprises a rotary drive device provided below the substrate holder and adapted to rotate the substrate holder in the enclosed space inside the reaction chamber. Therefore, when a relatively bigger substrate is carried on the substrate holder, the substrate is rotated inside the reaction chamber during deposition. When multiple relatively smaller substrates are carried on the substrate holder, these substrates are moved in the reaction chamber during deposition.

Further, the magnetic field generator can be provided at left and right sides relative to the substrate holder, or at top and bottom side relative to the substrate holder. The magnetic field generator can be provided inside the reaction chamber. Alternatively, the magnetic field generator can be provided outside the reaction chamber. Either arranging the magnetic field generator inside the reaction chamber or outside the reaction chamber can enhance ionization of applied gas and increase the uniformity of the thickness of deposition of metal substance on the surface of the substrate(s).

The chemical vapor deposition reactor further comprises at least one power supply electrically connected to at least one of the gas heater, the substrate heater, the hot filaments and the magnetic field generator.

The chemical vapor deposition reactor further comprises an electrode grid provided in the enclosed space inside the reaction chamber, and a bias voltage power supply electrically connected to the electrode grid and the substrate holder to cause the electrode grid and the substrate holder to produce relative electrodes, thereby enhancing ionization of applied gas in the reaction chamber and increasing the uniformity of the thickness of deposition of metal substance on the surface of the substrate(s).

Alternatively, a bias voltage power supply may be used and electrically connected to the hot filaments and the substrate holder, causing the hot filaments and the substrate holder to produce relative electrodes, thereby enhancing ionization of applied gas in the reaction chamber and increasing the uniformity of the thickness of deposition of metal substance on the surface of the substrate(s).

### BRIEF DESCRIPTION OF THE DRAWINGS

FIG. 1 is a schematic drawing of a chemical vapor deposition reactor in accordance with a first embodiment of the present invention.

FIG. 2 is a schematic drawing of a chemical vapor deposition reactor in accordance with a second embodiment of the present invention.

FIG. 3 is a schematic drawing of a chemical vapor deposition reactor in accordance with a third embodiment of the present invention.

FIG. 4 is a schematic drawing of a chemical vapor deposition reactor in accordance with a fourth embodiment of the present invention.

### DETAILED DESCRIPTION OF THE PREFERRED EMBODIMENT

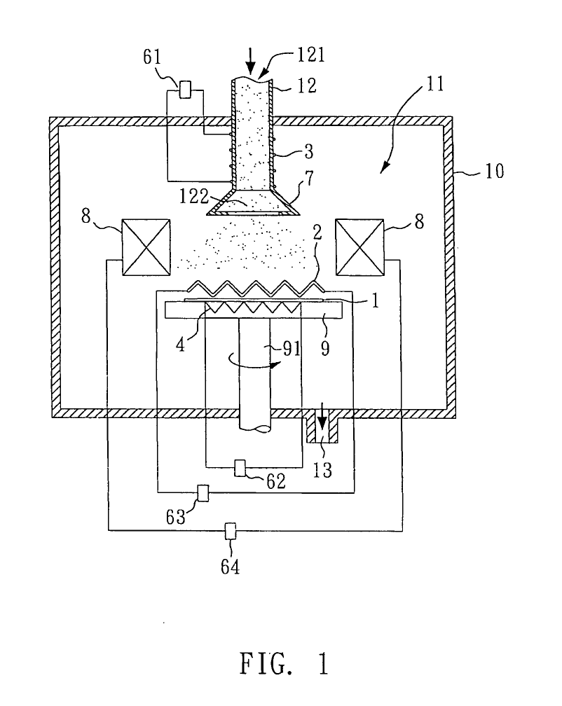

FIG. 1 is a schematic drawing of a chemical vapor deposition reactor in accordance with a first embodiment of the present invention. As shown in FIG. 1, the chemical vapor deposition reactor comprises a reaction chamber 10, a gas heater 3, a substrate holder 9, a substrate heater 4, a rotary drive device 91, a plurality of hot filaments 2, a magnetic field generator 8, and four power supplies 61,62,63,64.

Referring to FIG. 1 again, the reaction chamber 10 has an enclosed space 11, a gas intake pipe 12, and an exhaust port 13. The gas intake pipe 12 has an inlet 121 and an outlet 122. According to this embodiment, the outlet 122 of the gas intake pipe 12 is suspending in the enclosed space 11, and the inlet 121 of the gas intake pipe 12 is disposed at the top side of the enclosed space 11 of the reaction chamber 10, i.e., applied gas is supplied to the enclosed space 11 from the top side of the reaction chamber 10. The exhaust port 13 is disposed at the bottom side of the enclosed space 11 of the reaction chamber 10, i.e., exhaust gas is carried out of the enclosed space 11 through the bottom side of the reaction chamber 10, thereby increasing the uniformity of the distribution of applied gas in the enclosed space 11 of the reaction chamber 10. Further, the gas intake pipe 12 in the reaction chamber 10 is a vertical pipe. A gas shower 7 is provided at the outlet 122 of the gas intake pipe 12 to spray applied gas over the substrate 1 evenly, increasing the uniformity of the thickness of deposition of metal substance on the surface of the substrate 1.

Further, the aforesaid gas heater 3 is mounted inside the enclosed space 11 of the reaction chamber 10 around the outlet 122 of the gas intake pipe 12, i.e. applied gas that enters the gas intake pipe 12 is pre-heated inside the enclosed space 11 of the reaction chamber 10.

Further, as shown in FIG. 1, the substrate holder 9 is pivotally provided in the enclosed space 11 inside the reaction chamber 10, holding a substrate 1 for receiving a chemical vapor deposition work. The rotary drive device 91 is provided at the bottom side of the substrate holder 9, and controlled to rotate the substrate holder 9. The substrate heater 4 is provided around the substrate holder 9, and adapted to heat the substrate 1 that is carried on the substrate holder 9. According to this embodiment, the substrate 1 to be processed is carried on the substrate holder 9, and the rotary drive device 91 is controlled to rotate the substrate holder 9 during running of the chemical vapor deposition work, therefore the substrate 1 is rotated in the reaction chamber 10, increasing the uniformity of the thickness of deposition of metal substance on the surface of the substrate 1.

Further, as shown in FIG. 1, the aforesaid hot filaments 2 are arranged in the enclosed space 11 inside the reaction chamber 10, forming a coating face corresponding to the surface of the substrate 1 at the substrate holder 9 for heating the substrate 1. The magnetic field generator 8 is provided in the enclosed space 11 inside the reaction chamber 10 at left and right sides relative to the substrate holder 9 to enhance ionization of applied gas in the reaction chamber 10.

Further, the aforesaid power supplies 61˜64 are respectively electrically connected to the gas heater 3, the substrate heater 4, the hot filaments 2 and the magnetic field generator 8 to provide the necessary working voltage.

During operation, applied gas is pre-heated in the gas intake pipe 12 by the gas heater 3, the substrate 1 carried on the substrate holder 9 is heated by the substrate heater 4, and at the same time, the hot filaments 2 are controlled to heat the substrate 1 and the magnetic field generator 8 is controlled to generate a magnetic field, enhancing the ionization of applied gas in the reaction chamber 10 to increase the uniformity of the thickness of deposition of metal substance on the surface of the substrate 1. Therefore, the invention heat applied gas and the substrate 1 quickly, saving much deposition time and improving the coating efficiency. When performing diamond coating, the gas heater 3 preheats applied gas in the gas intake pipe 12 to 200° C.˜900° C., the substrate heater 4 heats the substrate 9 to 300° C.˜1000° C., and the hot filaments 2 is heated to 1800° C.˜2400° C.

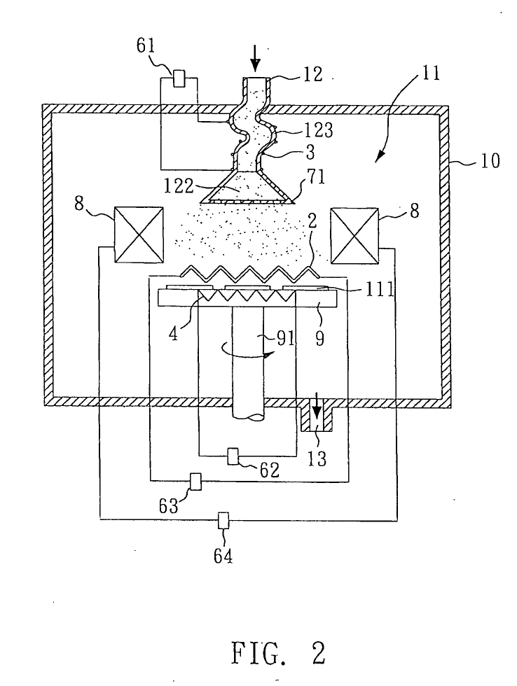

FIG. 2 is a schematic drawing of a chemical vapor deposition reactor in accordance with a second embodiment of the present invention. This second embodiment is substantially similar to the aforesaid first embodiment with the exception that the gas intake pipe 12 in the reaction chamber 10 according to this second embodiment is formed of a snake-shape pipe 123 that extends the gas delivery path in the reaction chamber 10, thereby enhancing the pre-heating effect. Further, a distribution pipe 71 is connected to the outlet 122 of the gas intake pipe 12. According to this embodiment, the substrate holder 9 holds three relatively smaller substrates 111 (when compared to the substrate 1 to be process in the aforesaid first embodiment) for coating. The rotary drive device 91 is controlled to rotate the substrate holder 9, thereby moving the three substrates 111 in the reaction chamber 10 during coating to increase the uniformity of coating thickness on the substrates 111.

By means of the application of multiple heater means and the arrangement of the magnetic field generator 8 at left and right sides relative to the substrate holder 9, this second embodiment achieves the same effects of enhancing ionization of applied gas in the reaction chamber 10, increasing the uniformity of the thickness of deposition of metal substance on the surface of the substrates 111, accelerating gas and substrate heating speed, shortening film-coating time and improving film-coating efficiency as what the aforesaid first embodiment does.

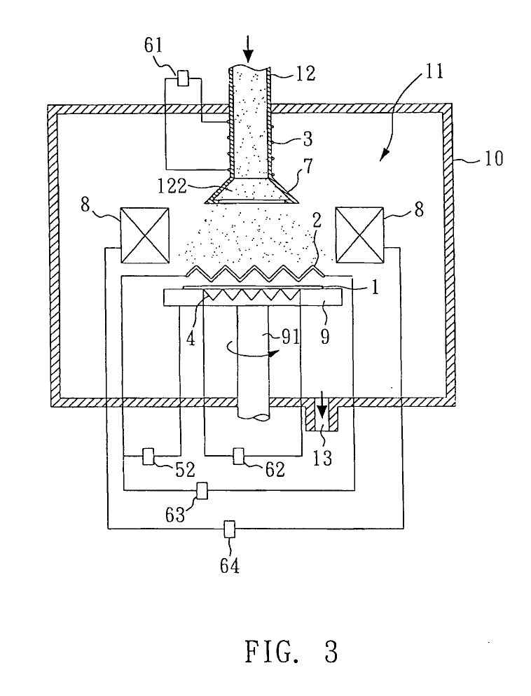

FIG. 3 is a schematic drawing of a chemical vapor deposition reactor in accordance with a third embodiment of the present invention. This third embodiment is substantially similar to the aforesaid first embodiment with the exception of the use of a bias voltage power supply 52, which is electrically connected to the hot filaments 2 and the substrate holder 9 to cause the hot filaments 2 and the substrate holder 9 to produce relative electrodes, thereby enhancing ionization of applied gas in the reaction chamber 10 and increasing the uniformity of the thickness of deposition of metal substance on the surface of the substrate 1.

By means of the application of multiple heater means and the arrangement of the magnetic field generator 8 at left and right sides relative to the substrate holder 9 and the relative electrodes at the hot filaments 2 and the substrate holder 9, this third embodiment achieves the same effects of enhancing ionization of applied gas in the reaction chamber 10, increasing the uniformity of the thickness of deposition of metal substance on the surface of the substrate 1, accelerating gas and substrate heating speed, shortening film-coating time and improving film-coating efficiency as what the aforesaid first and second embodiments do.

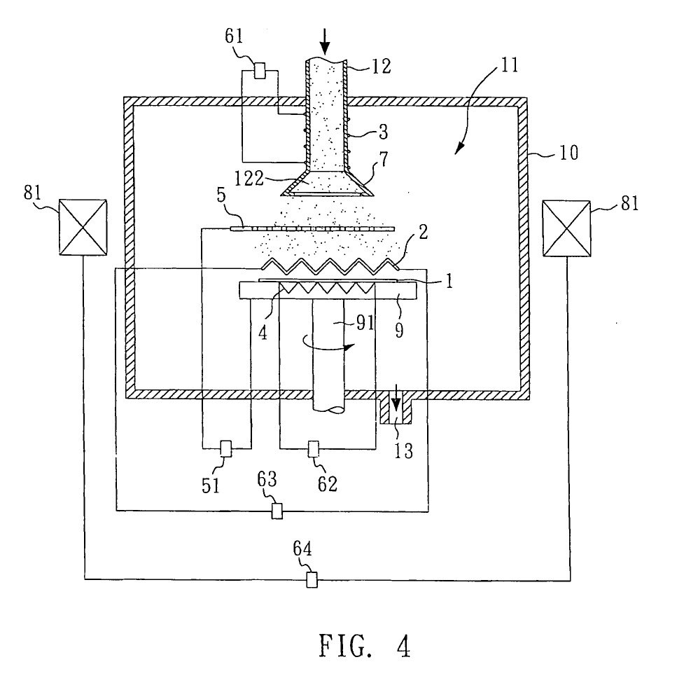

FIG. 4 is a schematic drawing of a chemical vapor deposition reactor in accordance with a fourth embodiment of the present invention. This fourth embodiment is substantially similar to the aforesaid first embodiment with the exception of the use of an electrode grid 5 and a bias voltage power supply 51. Further, according to this fourth embodiment, the magnetic field generator 81 is provided outside the reaction chamber 10. The electrode grid 5 is mounted inside the enclosed space 11 of the reaction chamber 10. The bias voltage power supply 51 is electrically connected to the electrode grid 5 and the substrate holder 9. By means of the bias voltage power supply 51, the electrode grid 5 and the substrate holder 9 produce relative electrodes, thereby enhancing ionization of applied gas in the reaction chamber 10 and increasing the uniformity of the thickness of deposition of metal substance on the surface of the substrate 1.

By means of the application of multiple heater means and the arrangement of the magnetic field generator 81 at left and right sides outside the reaction chamber 10 and the relative electrodes at the electrode grid 5 and the substrate holder 9, this fourth embodiment achieves the same effects of enhancing ionization of applied gas in the reaction chamber 10, increasing the uniformity of the thickness of deposition of metal substance on the surface of the substrate 1, accelerating gas and substrate heating speed, shortening film-coating time and improving film-coating efficiency as what the aforesaid three embodiments do.

Although the present invention has been explained in relation to its preferred embodiments, it is to be understood that many other possible modifications and variations can be made without departing from the spirit and scope of the invention as hereinafter claimed.

What is claimed is:

1. A chemical vapor deposition reactor comprising:
a reaction chamber, said reaction chamber having an enclosed space, a gas intake pipe, and an exhaust port, said gas intake pipe having an outlet suspending in the enclosed space inside said reaction chamber;
a gas heater disposed adjacent to said gas intake pipe and adapted to heat an applied gas being supplied to said gas intake pipe;
a substrate holder provided in the enclosed space inside said reaction chamber;
a substrate heater mounted in the enclosed space inside said reaction chamber around said substrate holder and adapted to heat said substrate holder;
a plurality of hot filaments arranged in the enclosed space inside said reaction chamber adjacent to said substrate holder; and
a magnetic field generator provided at two opposite sides relative to said substrate holder.

2. The chemical vapor deposition reactor as claimed in claim 1, wherein said gas intake pipe is a snake-shape pipe.

3. The chemical vapor deposition reactor as claimed in claim 1, wherein said gas heater is mounted in the enclosed space inside said reaction chamber and around the periphery of said gas intake pipe.

4. The chemical vapor deposition reactor as claimed in claim 3, wherein said gas heater is mounted in the outlet of said gas intake pipe.

5. The chemical vapor deposition reactor as claimed in claim 1, further comprising a gas shower mounted in the outlet of said gas intake pipe.

6. The chemical vapor deposition reactor as claimed in claim 1, further comprising a distribution pipe connected to the outlet of said gas intake pipe in the enclosed space inside said reaction chamber.

7. The chemical vapor deposition reactor as claimed in claim 1, further comprising a rotary drive device provided below said substrate holder and adapted to rotate said substrate holder in the enclosed space inside said reaction chamber.

8. The chemical vapor deposition reactor as claimed in claim 1, wherein said magnetic field generator is provided at left and right sides relative to said substrate holder.

9. The chemical vapor deposition reactor as claimed in claim 1, wherein said magnetic field generator is provided in the enclosed space inside said reaction chamber.

10. The chemical vapor deposition reactor as claimed in claim 1, wherein said magnetic field generator is provided outside said reaction chamber.

11. The chemical vapor deposition reactor as claimed in claim 1, further comprising at least one power supply electrically connected to at least one of said gas heater, said substrate heater, said hot filaments and said magnetic field generator.

12. The chemical vapor deposition reactor as claimed in claim 1, further comprising an electrode grid provided in the enclosed space inside said reaction chamber, and a bias voltage power supply electrically connected to said electrode grid and said substrate holder.

13. The chemical vapor deposition reactor as claimed in claim 1, further comprising a bias voltage power supply electrically connected to said hot filaments and said substrate holder.
